(19) United States
(12) Patent Application Publication
(10) Pub. No.: US 2012/0100796 A1
(43) Pub. Date: Apr. 26, 2012

(54) CONTAINER-TYPE DATA CENTER

(76) Inventors: Jun ZHAO, Shenzhen (CN); Zhenyu ZHUANG, Shenzhen (CN); Hangkong HU, Shenzhen (CN); Yonghui PENG, Shanghai (CN); Mingliang HAO, Shenzhen (CN); Dongli WANG, Shenzhen (CN); Na WEI, Shenzhen (CN); Tiesheng ZHANG, Shenzhen (CN); Youhe KE, Shenzhen (CN)

(21) Appl. No.: 13/339,249

(22) Filed: Dec. 28, 2011

Related U.S. Application Data
(63) Continuation of application No. PCT/CN2010/079686, filed on Dec. 13, 2010.

(30) Foreign Application Priority Data
Jan. 20, 2010 (CN) 201010042877.9

(51) Int. Cl. H05K 5/02

(52) U.S. Cl. 454/184

(57) ABSTRACT

A container-type data center is provided in embodiments of the present invention, including a container, cabinets, computing devices, and cooling devices. The cabinets are arranged in rows inside the container. The computing devices are set inside the cabinets. Air enters from one side of each of the cabinets and exhausts from another side to form left-to-right air vents. The left-to-right air vents are connected in series. In the series air vents of the cabinets, multiple cooling devices are set. In the container, a maintenance passage is formed for maintaining the cabinets. Maintenance planes of the cabinets face the maintenance passage. In the embodiments of the present invention, the air enters from one side of each of the cabinets and exhausts from the other side to form the left-to-right air vents, and the maintenance planes of the cabinets face the maintenance passage. In this way, the maintenance convenience is greatly improved.

### CROSS-REFERENCE TO RELATED APPLICATIONS

This application is a continuation of International Application No. PCT/CN2010/079686, filed on Dec. 13, 2010, which claims priority to Chinese Patent Application No. 201010042877.9, filed on Jan. 20, 2010, both of which are hereby incorporated by reference in their entireties.

### FIELD OF THE INVENTION

The present invention relates to the field of communications technologies, and in particular, to a container-type data center.

### BACKGROUND OF THE INVENTION

The container-type data center is a mini data center solution that features low cost, high integration degree, high energy efficiency, high flexibility, and fast deployment, and is gradually used by major operators. Different vendors propose different deployment or maintenance solutions to address the problem of deploying a container-type data center with the requirements of high density and small maintenance space.

A container-type data center according to the existing technology includes a container, and two rows of cabinets at both sides of the container. The maintenance plane of each cabinet is vertical to the sidewall of the container. Two sidewalls of the container are the two long sides of the container, and the two short sides are the front door and back door of the container. The solid line in the figure shows a state when the front door and back door of the container are closed. The dotted line indicates a state when the doors are open for maintenance personnel to enter into the container for device maintenance.

The container-type data center further includes a cooling device. The cooling device includes a fan and a gas-liquid heat exchanger. The cooling device is set at a side of each cabinet. That is, cooling devices are arranged at intervals between cabinets. The fan blows the air flow cooled by the gas-liquid heat exchanger to the device in the cabinet, and blows away the heat surrounding the device. The two rows of cabinets standing at the sidewalls of the container and the cooling devices that are arranged at intervals between the cabinets form air vents respectively. A partition wall is arranged between the front door of the container and one end of the two rows of cabinets to form a front door compartment. A partition wall is arranged between the back door of the container and another end of the two rows of cabinets to form a back door compartment.

The back door compartment is used to place the switch cabinet. At the back door of the container, an internal door is used to connect the ends of both rows of cabinets. The internal door and the partition wall of the back door of the container form an enclosed cavity. The front door compartment, the enclosed cavity, the two rows of cabinets, and cooling devices connect the air vents at both sides of the container to form an enclosed air vent loop.

Lateral planes of the two rows of the cabinets is closedly attached to the sidewall of the container, and the side and the other side form a middle passage. Devices can be pulled out by using maintenance forklifts to the passage for maintenance.

During implementation of the present invention, the inventor finds the prir art has at least the following problems: Lateral planes of cabinets are attached to the sidewall of the container, so the maintenance plane is hidden inside, the running status indications of devices cannot be viewed, cabinets need to be moved in daily maintenance and check, and special tools, such as forklifts, need to be used to pull out the cabinets to the passage for maintenance. As a result, a large amount of time and energy are consumed during maintenance and the maintenance cost is high.

### SUMMARY

A container-type data center is provided in an embodiment of the present invention to implement maintenance on a cabinet in a container-type data center without moving the cabinet.

A container-type data center is provided in an embodiment of the present invention, including a container, cabinets, computing devices, and cooling devices. The cabinets are arranged in rows inside the container. The computing devices are set inside the cabinets. Air enters from one side of each of the cabinets and exhausts from another side to form left-to-right air vents. The left-to-right air vents are connected in series. Multiple cooling devices are set in the series air vents of the cabinets. In the container, a maintenance passage is formed for maintaining the cabinets. Maintenance planes of the cabinets face the maintenance passage.

In the embodiment of the present invention, the air enters from one side of each of the cabinets and exhausts from another side to form left-to-right air vents, and the maintenance planes of the cabinets face the maintenance passage, so maintenance personnel can maintain devices without moving cabinets or using special tools to pull out devices to the maintenance passage. In this way, the maintenance convenience is greatly improved, and maintenance time and cost are reduced.

### BRIEF DESCRIPTION OF THE DRAWINGS

To make the technical solutions of the present invention clearer, the accompanying drawings for illustrating embodiments of the present invention or the prior art are outlined below. Apparently, the accompanying drawings to be described are merely some embodiment of the present invention, and persons skilled in the art can derive other drawings from such accompanying drawings without any creative effort.

FIG. 1 is a vertical view structural diagram of a container-type data center in the prior art;

FIG. 2 is a structural diagram of a container-type data center when a top cover is removed according to a first embodiment of the present invention;

FIG. 3 is a vertical view structural diagram of a container-type data center according to the first embodiment of the present invention;

FIG. 4 is a side view structural diagram of a container-type data center according to the first embodiment of the present invention;

FIG. 5 is a schematic diagram of air flowing into and out of cabinets in a container-type data center according to the first embodiment of the present invention; and

FIG. 6 is a vertical view structural diagram of a container-type data center according to a second embodiment of the present invention.

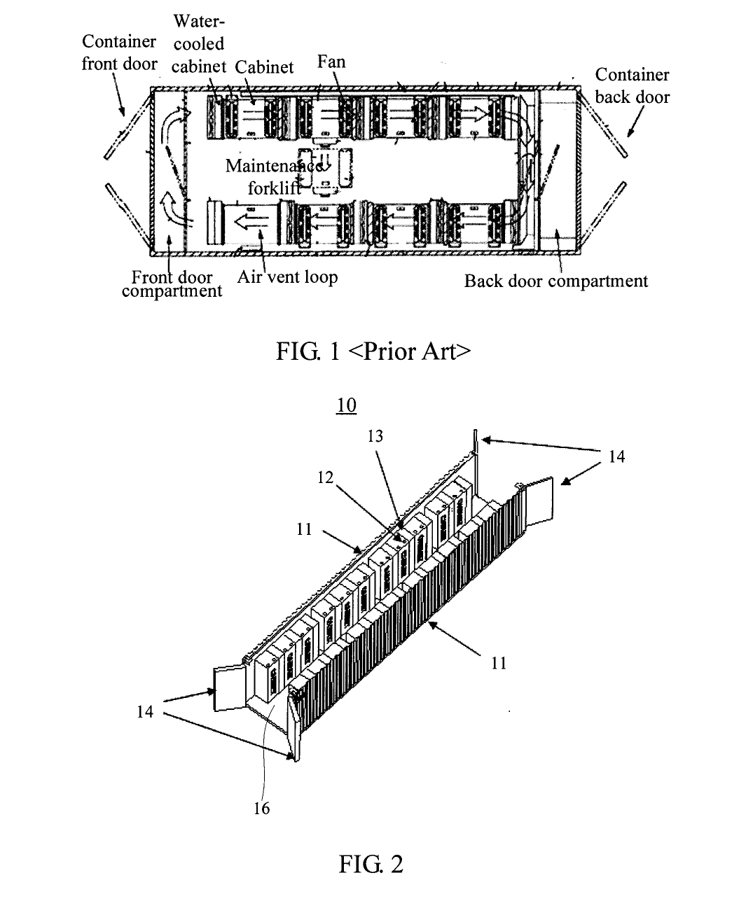

### DETAILED DESCRIPTION

To make purposes, technical solutions, and advantages of the present invention clearer, the following further describes the present invention with reference to drawings and embodiments. It should be understood that embodiments to be described are used only to explain but not to confine the present invention.

A container-type data center provided in an embodiment of the present invention includes a container, cabinets, computing devices, and cooling devices. The cabinets are arranged in rows inside the container. The computing devices are set inside the cabinets. Air enters from one side of each of the cabinets and exhausts from another side to form left-to-right air vents. The left-to-right air vents are connected in series. In the series air vents of the cabinets, multiple cooling devices are set. In the container, a maintenance passage is formed for maintaining the cabinets. Maintenance planes of the cabinets face the maintenance passage.

A sidewall of the container in the embodiment of the present invention is a long side of the container. The cabinets can be set in the middle of the container in one row, can be set along the sidewall of the container in two rows in a face-to-face manner, or can be set in the middle of the container in a back-to-back manner. When set face to face, each row of cabinet is close to the sidewall of the container, and a maintenance passage is formed between the maintenance planes of the two rows of cabinets. When set back to back, the two rows of cabinets are set in the back-to-back manner in the middle of the container, a maintenance plane of each row faces a sidewall of the container, and the maintenance planes of the two rows and sidewalls of the container form a maintenance passage.

FIG. 2 is a structural diagram of a container-type data center when a top cover is removed according to a first embodiment of the present invention. The container-type data center includes a container, and two rows of cabinets 12 set face to face close to two sidewalls 11 of the container. Maintenance planes of the two rows of cabinets are in parallel to the two sidewalls 11 of the container. The maintenance planes of the two rows of cabinets form a maintenance passage 16 in the container.

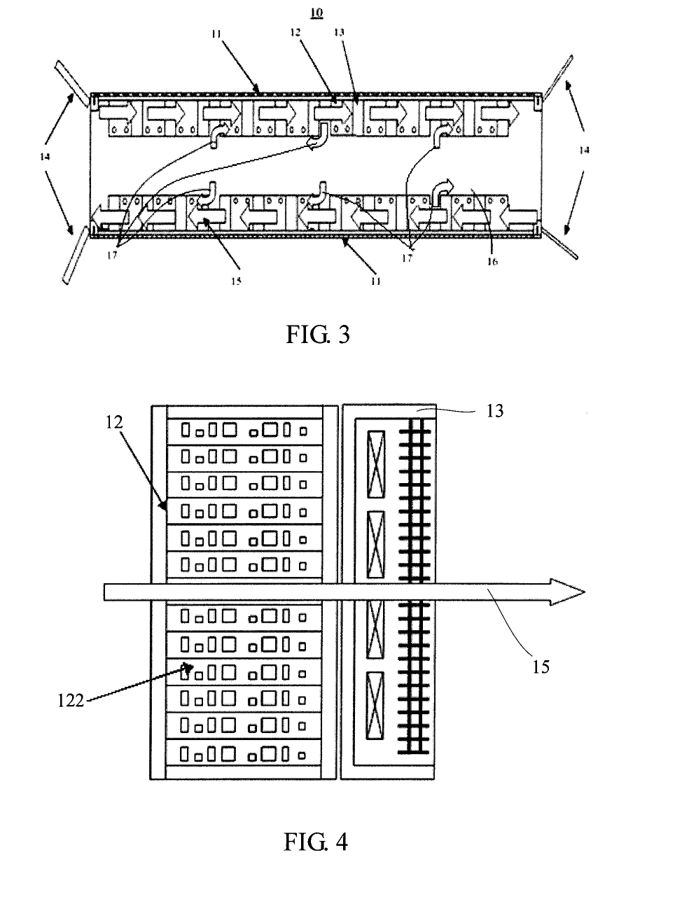

According to FIG. 3, the container-type data center further includes cooling devices 13 set in the cabinets 12. Each of the cooling devices 13 includes a fan and a gas-liquid heat exchanger. Air enters from one side of each of the cabinets 12 and exhausts from the other side to form left-to-right air vents. The left-to-right air vents are connected in series. In the series air vents of the cabinets, multiple cooling devices 13 are set. The two rows of cabinets 12 that are arranged at the sidewalls of the container and the cooling devices 13 that are arranged between the cabinets form air vents 15 respectively. The container further includes two end doors 14 that connect the two sidewalls 11 of the container, that is, a front door and a back door of the container.

In another embodiment, a certain gap (as indicated by a mark number 17 in the figure) exists between the cooling devices and a part of the cabinets and is used to supplement air intake for the cabinets, so that when air volumes required by cabinets at both sides are inconsistent, an external air intake or exhaust space is provided to better implement air intake and sufficient air volumes are provided for the cabinets to implement high-efficiency heat dissipation.

It can be understood that a certain space exists between a cabinet or cooling device at the end of a row and an end door 14 of the container to serve as an air intake or exhaust space for the cabinet or cooling device at the end of the row.

In the two rows of cabinets 12, an air outlet of a previous cabinet faces an air inlet of a next cabinet. Between cabinets, a cooling device 13 cools heated air exhausted by a cabinet, so that the air inlet of the next cabinet and the inside of the entire container form a cooled air space.

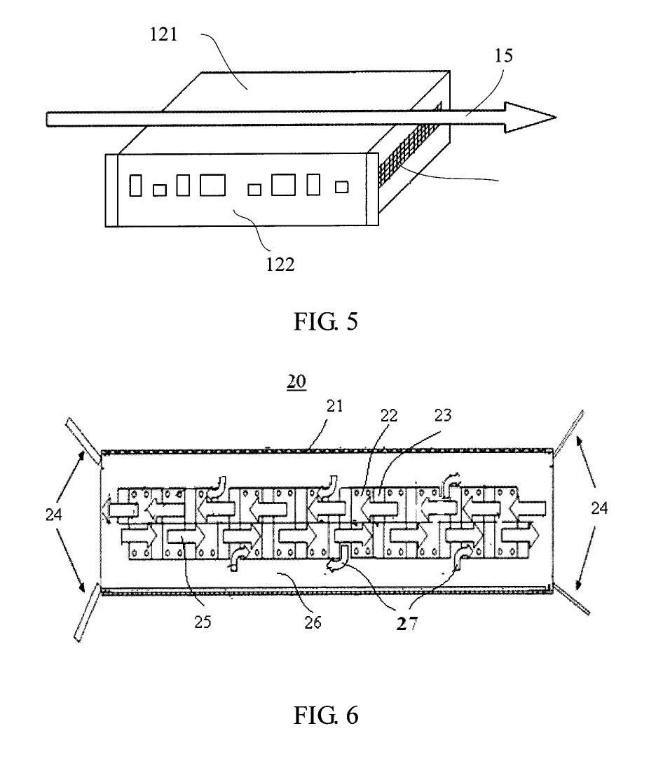

Referring FIG. 4, FIG. 4 is a side view structural diagram of a cabinet 12 and a cooling device 13 in the container-type data center according to the first embodiment of the present invention. As shown in FIG. 4, a maintenance plane 122 of the cabinet 12 faces the maintenance passage 16, and the cooling device 13 is set at one side of the cabinet 12. Each cabinet 12 has only a front door but no back door. All maintenance planes 122 are at the front sides, and no maintenance is required to be performed at the back door. No sidewall cover exists at both sides of the cabinet 12. Referring to FIG. 5, different from an air intake manner at the maintenance plane for a traditional server device, the air intake manner at the maintenance plane for a device in the cabinet 12 has the side-in side-out air vent structure, as indicated by a mark number 15 in the figure. An interface and a maintenance plane of the device in the cabinet 12 face the maintenance passage 16. In addition, the device, such as a computing device of the data center, in the cabinet 12 in embodiment of the present invention is horizontally inserted device. The computing devices are horizontally mounted in the cabinets, so that directions of the computing devices are the same as the air directions of the air vents.

In the embodiment of the present invention, an air flow cooled by the cooling device enters from one sidewall of the cabinet and is exhausted from the other sidewall, and the maintenance plane of the cabinet is set with face to the maintenance passage. Maintenance personnel maintain devices without moving cabinets or using special tools to pull out devices to the maintenance passage. In this way, the maintenance convenience is greatly improved, and maintenance time and cost are reduced. In addition, the maintenance plane is set with face to the maintenance passage. Therefore, all interfaces of devices in the cabinets are at the front side, and the requirement of high-density cabling is met.

Referring to FIG. 6, FIG. 6 is a vertical view structural diagram of a container-type data center according to a second embodiment of the present invention. The container-type data center includes a container, and two rows of cabinets 22 that are set face to face. Maintenance planes of the two rows of cabinets are in parallel to sidewalls 21 of the container. The maintenance planes of the two rows of cabinets 22 form a maintenance passage 26 in the container. Different from that the maintenance passage 16 in the first embodiment is formed by the maintenance planes of the two rows of cabinets 12, the maintenance passage 26 in the second embodiment of the present invention is formed by the two rows of cabinets 22 and the two sidewalls 21 of the container. Maintenance personnel can enter the container through two end doors 24 of the container for device maintenance.

It can be understood that the container-type data center may further include cooling devices 23 set at one side of the cabinets 22. Each of the cooling device 23 includes a fan and a gas-liquid heat exchanger. Air enters from one side of each of the cabinets 22 and exhausts from the other side to form left-to-right air vents. The left-to-right air vents are connected in series. In the series air vents of the cabinets 22, multiple cooling devices 23 are set. The two rows of cabinets 22 that are arranged in the middle of the container and the cooling devices 23 that are arranged at intervals between the cabinets form air vents 25 respectively. In addition, devices mounted in the cabinets 12 in the embodiment of the present invention are horizontally inserted devices.

In another embodiment, a certain gap 27 that exists between the cooling devices and a part of the cabinets is used to supplement air intake for the cabinets, so that when air volumes required by cabinets at both sides are inconsistent, an external air intake or exhaust space is provided to better implement the air intake, and sufficient air volumes are provided for the cabinets to implement high-efficiency heat dissipation.

It can be understood that a certain space is reserved between a cabinet or a cooling device at the end of a row and an end door 24 of the container to serve as an air intake or exhaust space for the cabinet or cooling device at the end of the row.

In the two rows of cabinets 22, an air outlet of a previous cabinet faces an air inlet of a next cabinet. Between cabinets, a cooling device 23 cools heated air exhausted by a cabinet, so that the air inlet of the next cabinet and the inside of the entire container form a cooled air space.

In the embodiments of the present invention, an air flow cooled by the cooling device enters from one sidewall of the cabinet and is exhausted from the other sidewall of the cabinet, and the maintenance plane of the cabinet is set with face to the maintenance passage.

Maintenance personnel maintain devices without moving cabinets or using special tools to pull out devices to the maintenance passage. In this way, the maintenance convenience is greatly improved, and maintenance time and cost are reduced. In addition, the maintenance plane is set with face to the maintenance passage, so all interfaces of devices in the cabinets are at a front side, and the requirement of high-density cabling is met.

In the embodiment of the present invention, the container-type data center can be moved through the container. In another embodiment, the data center can be moved through other movable containers. The cabinet in the embodiments of the present invention is a standard 19-inch cabinet. It can be understood that, in other embodiments, cabinets of other standard dimensions can be adopted.

In conclusion, the above are merely exemplary embodiments of the present invention. However, the protection scope of the present invention is not limited thereto. Changes or replacements readily derived by persons skilled in the art without departing from the technical scope disclosed by the present invention should fall within the protection scope of the present invention. Therefore, the protection scope of the present invention is subject to the appended claims.

What is claimed is:

1. A container-type data center, comprising a container, cabinets, computing devices, and cooling devices, wherein the cabinets are arranged in rows inside the container; the computing devices are set inside the cabinets; air enters from one side of each of the cabinets and exhausts from the another side to form left-to-right air vents; the left-to-right air vents are connected in series; in the series air vents of the cabinets, multiple cooling devices are set; in the container, a maintenance passage is formed for maintaining the cabinets; maintenance planes of the cabinets face the maintenance passage.

2. The container-type data center according to claim 1, wherein: the cabinets are arranged along sidewalls of the container in two rows, the two rows of cabinets are arranged face to face, and a gap between the two rows of cabinets forms the maintenance passage.

3. The container-type data center according to claim 1, wherein: the cabinets are set in the middle of the container in two rows, the two rows of cabinets are set back to back, a maintenance plane of each row of cabinets faces a sidewall of the container, and maintenance planes of the two rows of cabinets and sidewalls of the container form the maintenance passage.

4. The container-type data center according to claim 1, wherein: the cooling devices are set at intervals between the cabinets, and a cooling device is arranged at an air outlet side of a last cabinet of each row of cabinets.

5. The container-type data center according to claim 4, wherein: the cooling device comprises a fan and a gas-liquid heat exchanger.

6. The container-type data center according to claim 1, wherein: a certain space exists between a cabinet or cooling device at the end of each row of cabinets and an end door of the container to serve as an air intake or exhaust space for the cabinet or cooling device at the end of the row.

7. The container-type data center according to claim 1, wherein: a certain gap is reserved between the cooling devices and a part of the cabinets and is used to supplement air intake for the cabinets.

8. The container-type data center according to claim 1, wherein: devices that are horizontally inserted are mounted in the cabinets.

9. A container-type data center, comprising a container body, cabinets, and cooling devices, wherein the cabinets are used to install computing devices of the data center; the cabinets are arranged in rows inside the container; air enters from one side of each of the cabinets and exhausts from another side to form left-to-right air vents; the left-to-right air vents are connected in series; in the series air vents of the cabinets, multiple cooling devices are set; in the container, a maintenance passage is formed for maintaining the cabinets; maintenance planes of the cabinets face the maintenance passage.

10. The container-type data center according to claim 9, wherein: the cooling devices are arranged at intervals between the cabinets, and a cooling device is arranged at an air outlet side of a last cabinet of each row of cabinets.

11. A data center container, comprising a container body, and cabinets, wherein the cabinets are used to install computing devices of a data center; the cabinets are arranged in rows inside the container body; air enters from one side of each of the cabinets and exhausts from the other side to form left-to-right air vents; the left-to-right air vents are connected in series; in the series air vents of the cabinets, multiple cooling devices are set; in the container, a maintenance passage is formed for maintaining the cabinets; maintenance planes of the cabinets face the maintenance passage.

12. The data center container according to claim 11, further comprising computing devices, wherein the computing devices are horizontally mounted inside the cabinets so that the directions of the computing devices are the same as the directions of the air vents.

13. The data center container according to claim 11, further comprising cooling devices, wherein the cooling devices are mounted in the air vents to provide an air source for the air vents.
